(19) United States
(12) Patent Application Publication
(10) Pub. No.: US 2016/0330867 A1
(43) Pub. Date: Nov. 10, 2016

(54) ELECTROMAGNETIC HEAT TRANSFER CIRCUIT

(71) Applicant: SCHNEIDER ELECTRIC IT CORPORATION, West Kingston, RI (US)

(72) Inventor: Daniel J. Rohr, Wildwood, MO (US)

(21) Appl. No.: 15/108,906

(22) PCT Filed: Dec. 30, 2013
(86) PCT No.: PCT/US2013/078255

§ 371 Date: Jun. 29, 2016

(51) Int. Cl. H05K 7/20

(52) U.S. Cl. CPC H05K 7/20272; H05K 7/20281

(57) ABSTRACT

A heat transfer circuit includes a fluid flow passageway, a heat transfer fluid, a reservoir, at least one electromagnetic field coil, and a control module. The heat transfer fluid is disposed within the fluid flow passageway and includes at least one magnetic component. The reservoir may include a heat reservoir in thermal communication with the fluid flow passageway. The at least one electromagnetic field coil is arranged along at least a portion of the fluid flow passageway and is configured to generate a magnetic field. The control module is in communication with the at least one electromagnetic field coil to control the operation of the at least one electromagnetic field coil.

### BACKGROUND

1. Technical Field

The technical field relates generally to heat transfer, and more specifically, to systems and methods for transferring heat energy using fluids driven by magnetic fields.

2. Background Discussion

Conventional heat transfer systems often employ the use of direct-expansion (DX) units, which utilize the vapor-compression refrigeration cycle. These types of systems may often times create a lot of noise and contain moving parts that may wear down over time and eventually malfunction. The control electronics associated with these types of systems may be complicated and expensive. Further, the system may require installation challenges such as accommodating stresses related to vibration and fitting large pieces of equipment into a small footprint.

When a current is passed through a conducting material that is configured into a loop or several loops to form a coil, a magnetic field develops. The strength and uniformity of the magnetic field is proportional to both the applied current and the number of turns per unit length of the coil. These types of coils are conventionally found in electromagnetic machines, ranging from vacuum cleaners to mass spectrometers.

Ferrofluids are commonly used in audio equipment, such as loudspeakers, to remove heat from the voice coil. In certain instances, ferrofluids may become less magnetic at higher temperatures. For example, a strong magnet placed near a heat source, such as the voice coil, will attract cold ferrofluid more than hot ferrofluid and thus force the heated ferrofluid away from the voice coil.

### SUMMARY

In accordance with one or more embodiments, a heat transfer circuit is provided. The heat transfer circuit may include a fluid flow passageway and a heat transfer fluid disposed within the fluid flow passageway. The heat transfer fluid may include at least one magnetic component. The heat transfer circuit may further include at least one reservoir in thermal communication with the fluid flow passageway, at least one electromagnetic field coil arranged along at least a portion of the fluid flow passageway, and a control module in communication with the at least one electromagnetic field coil to control the operation of the at least one electromagnetic field coil. The electromagnetic field coil may be configured to generate a magnetic field.

Embodiments of the heat transfer circuit may include a plurality of electromagnetic field coils arranged sequentially. Each electromagnetic field coil of the plurality of electromagnetic field coils may have a positive pole and a negative pole, and the positive pole of each electromagnetic field coil may be positioned adjacent to the negative pole of an adjacent electromagnetic field coil of the sequential arrangement. A control module may be configured to activate each electromagnetic field coil sequentially in a first direction and a second direction. Each electromagnetic field coil of the plurality of electromagnetic field coils may be spaced substantially equidistant from each other.

The at least one reservoir may include a heat reservoir in thermal communication with a first portion of the fluid flow passageway. The at least one reservoir may further include a cooling reservoir in thermal communication with a second portion of the fluid flow passageway.

The at least one fluid flow passageway may be a tubular structure with an annular fluid chamber. In one or more embodiments, the fluid flow passageway may form a closed circuit. The fluid flow passageway may be constructed from a plurality of fluid flow passageway segments arranged sequentially. The heat transfer circuit may further include at least one heat transfer element positioned in a pair of adjacent fluid flow passageway segments, wherein the at least one heat transfer element is in thermal communication with the heat transfer fluid. A first heat transfer element may be in thermal communication with the heat reservoir and a second heat transfer element may be in thermal communication with the cooling reservoir.

According to at least one embodiment, the heat transfer fluid may further include an aqueous component. In one or more embodiments, the at least one magnetic component includes nanoparticles of iron.

According to one or more embodiments, a method of transferring thermal energy in a heat transfer circuit is provided. The method may include positioning at least one electromagnetic field coil along at least a portion of the fluid flow passageway, using the control module to apply power to the at least one electromagnetic field coil to generate a magnetic field that moves the heat transfer fluid through the fluid flow passageway, and passing the heat transfer fluid through the reservoir.

According to one or more embodiments, the at least one electromagnetic field coil may be a plurality of electromagnetic field coils and the method may further include positioning each electromagnetic field coil of the plurality of electromagnetic field coils sequentially along at least a portion of the fluid flow passageway, and using the control module to sequentially apply power to each electromagnetic field coil of the plurality of electromagnetic field coils in a first direction to move the heat transfer fluid through the fluid flow passageway in the first direction. In another embodiment, the method may further include using the control module to apply power to each electromagnetic field coil in a second direction, wherein the second direction is opposite the first direction. Each electromagnetic field coil may be controlled by a separate drive circuit.

In at least one embodiment, the heat transfer fluid includes at least one magnetic component, and a flow rate of the heat transfer fluid through the fluid flow passageway may be proportional to the concentration of the at least one magnetic component in the heat transfer fluid.

In certain embodiments, the reservoir includes a heat reservoir and a cooling reservoir, and passing the heat transfer fluid through the heat reservoir and the cooling reservoir is performed in a continuous circuit. Thermal energy may be transferred from the heat reservoir to the cooling reservoir through the heat transfer fluid.

Still other aspects, embodiments, and advantages of these exemplary aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed aspects and embodiments. Embodiments disclosed herein may be combined with other embodiments, and references to “an embodiment,” “an example,” “some embodiments,” “some examples,” “an alternate embodiment,” “various embodiments,” “one embodiment,” “at least one embodiment,” “this and other embodiments” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF DRAWINGS

Various aspects of at least one embodiment are discussed below with reference to the accompanying figure, which is not intended to be drawn to scale. The figure is included to provide an illustration and a further understanding of the various aspects and embodiments, and is incorporated in and constitutes a part of this specification, but is not intended as a definition of the limits of any particular embodiment. The drawing, together with the remainder of the specification, serves to explain principles and operations of the described and claimed aspects and embodiments. For purposes of clarity, not every component may be labeled in the figure. In the figure:

FIG. 1 is an illustration of an example of a heat transfer circuit in accordance with one or more embodiments disclosed herein.

### DETAILED DESCRIPTION

By way of introduction, aspects of this disclosure relate to heat transfer circuits that utilize at least one electromagnetic field coil. The electromagnetic field coil may be arranged along a fluid flow passageway that contains heat transfer fluid. When electric current is applied to the electromagnetic field coil a magnetic field is created. Magnetic particles in the heat transfer fluid are attracted to the magnetic field and thereby “pull” the fluid through the fluid flow passageway. The fluid flow passageway may further be in thermal communication with a heat reservoir and a cooling reservoir. A heat transfer circuit may be created by passing the fluid through the heat reservoir, where it absorbs heat through the walls of the fluid flow passageway. The fluid may then be passed through the cooling reservoir, where at least a portion of the heat is expelled.

One or more advantages of the heat transfer circuit disclosed herein may include high efficiencies, due to the minimal use of moving parts and the minimal amount of required input energy. Further, the system produces minimal pollutants to the environment, such as exhaust and noise. In addition, the system is flexible and scalable, allowing for the ability to be arranged in a number of different layouts.

The aspects disclosed herein in accordance with the present invention, are not limited in their application to the details of construction and the arrangement of components set forth in the following description or illustrated in the accompanying drawings. These aspects are capable of assuming other embodiments and of being practiced or of being carried out in various ways. Examples of specific implementations are provided herein for illustrative purposes only and are not intended to be limiting. In particular, acts, components, elements, and features discussed in connection with any one or more embodiments are not intended to be excluded from a similar role in any other embodiments.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. In addition, in the event of inconsistent usages of terms between this document and documents incorporated herein by reference, the term usage in the incorporated reference is supplementary to that of this document; for irreconcilable inconsistencies, the term usage in this document controls. Moreover, titles or subtitles may be used in the specification for the convenience of a reader, which shall have no influence on the scope of the present invention.

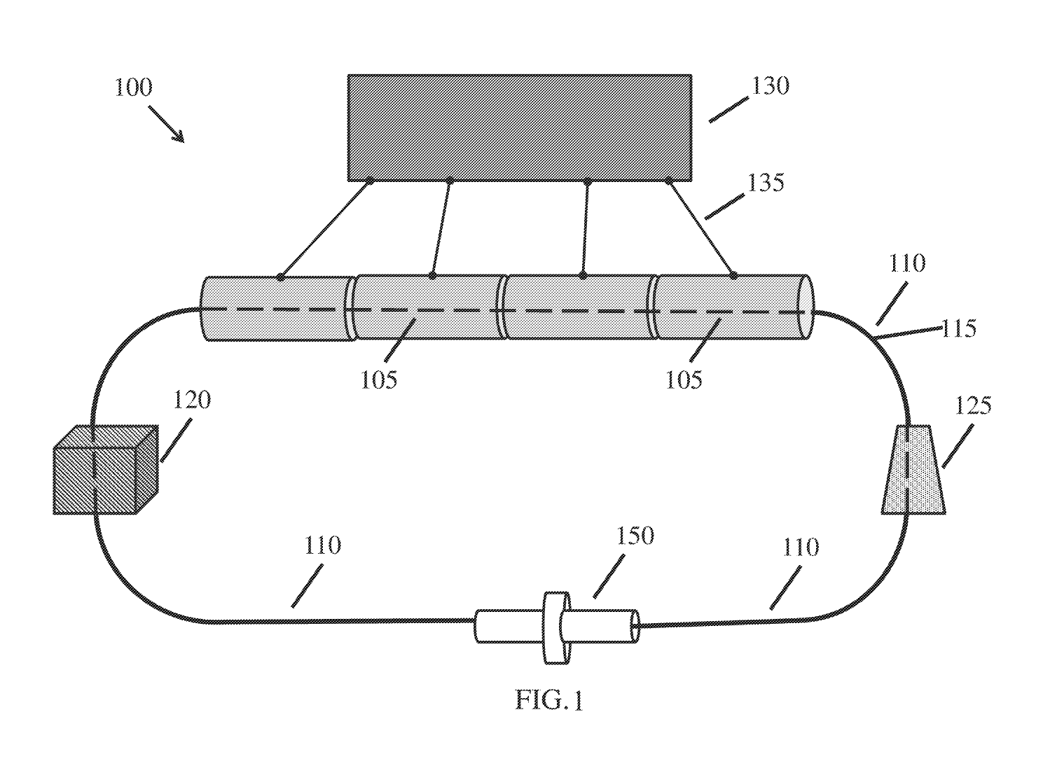

In accordance with one or more embodiments, a heat transfer circuit is provided. Referring to FIG. 1, a heat transfer circuit 100 includes one or more electromagnetic field coils 105. As used herein, the term “electromagnetic field coil” refers to a coil constructed from a conductive material that generates a magnetic field when current is applied. As will be appreciated by those skilled in the art, the coils may be constructed of conductive wires, bars, or plates, which are wound, or cut, to form a coil structure. For example, the electromagnetic field coils 105 may be constructed from copper or aluminum tubes or plates, or other similar metals or metal alloys. The physical configuration for each electromagnetic field coil 105 may be adapted to the individual requirements of the heat transfer circuit 100. For example, the number of coils per unit length may be dictated by the size and desired thermal capacity of the heat transfer circuit 100. Increasing the number of coils per unit length may increase the strength of the resulting magnetic field, and the system may be sized accordingly. Further, the open interior region of the electromagnetic field coils 105 may be sized to allow for one or more tubular fluid flow passageways (discussed further below) to be disposed within.

In some embodiments, a plurality of electromagnetic field coils 105 may be used. According to a further aspect, the electromagnetic field coils 105 may be arranged sequentially along one or more portions of a fluid flow pathway 110. For example, each coil may be placed adjacent another coil in a longitudinal direction. In a further aspect, each coil may be spaced equidistant from an adjacent coil. Each electromagnetic field coil may have a negative pole and a positive pole. When arranged sequentially, the polarity of each coil may be oriented in the same direction. For example, the positive poles of each coil may all face the same direction, so that the positive pole of each electromagnetic field coil is positioned adjacent to the negative pole of an adjacent electromagnetic field coil. Each coil may be activated in sequence to drive a heat transfer fluid 115 through the fluid flow passageway 110.

In certain embodiments, the electromagnetic field coils 105 may be covered or surrounded by an insulating material. The insulating material may be configured to cover or surround each separate coil, or may be configured to cover the coil in its entirety. For example, the insulating material may be shaped like a cylinder with a hollow core. The cylindrical electromagnetic field coil 105 may be disposed within the cylindrical insulating material, leaving the hollow core open for a tubular fluid flow passageway (discussed further below). In certain instances, the insulating material may be configured to absorb electric current and at the same time transmit a magnetic field. Further, the insulating material may be configured to absorb heat that may emanate from the electromagnetic field coil.

As described, the heat transfer circuit 100 includes the heat transfer fluid 115 provided in the fluid flow passageway 110. As illustrated in FIG. 1 by the dashed line, the fluid flow passageway 110 may be configured to be disposed within one or more of the electromagnetic field coils 105. According to some embodiments, the fluid flow passageway 110 may be a tubular structure. The tubular structure may further include an annular fluid chamber, through which the heat transfer fluid 115 may flow. Since the magnetic field needs to be capable of permeating the fluid flow passageway 110, the fluid flow passageway 110 may be constructed from non-ferromagnetic materials. The fluid flow passageway 110 may be made from a thermally conductive material that allows for heat transfer and also exhibits electric insulating properties. For example, the fluid flow passageway may be constructed from rubber, including synthetic rubber, or other polymeric tubing.

In certain embodiments, the fluid flow passageway 110 may have a varying diameter or cross section. In some embodiments, the fluid flow passageway 110 may comprise additional heat transfer enhancements. For example, internal fins or baffles may be attached to the inside walls of at least a portion of the fluid flow passageway 110.

One or more of the electromagnetic field coils 105 may be arranged along at least a portion of the fluid flow passageway 110. For example, FIG. includes four separate electromagnetic field coils arranged sequentially around a section of the fluid flow passageway 110. In some embodiments, the electromagnetic field coils 105 may be arranged along multiple portions of the fluid flow passageway.

In at least one embodiment, the fluid flow passageway 110 contains the heat transfer fluid 115. For example, the heat transfer fluid 115 may be disposed within the fluid flow passageway 110. In various embodiments, the heat transfer fluid 115 may comprise at least one magnetic component. Non-limiting examples of magnetic components may include magnetic powders, such as ferrite particles, iron (Fe) particles, sendust (Fe—Si—Al) particles, MPP (Ni—Mo—Fe) particles, Ni—Fe particles, Fe—Si-alloy particles, iron-based amorphous powder particles, cobalt-based amorphous powder particles, or other equivalent materials known in the art. For example, the magnetic component may include iron-based powder or nanoparticles of iron. In at least one embodiment, ferrofluid may be used as the heat transfer fluid. An example of such a material is available from Apex Magnets (Petersburg, W.Va.). The magnetic component further may be coated with a surfactant to provide a more homogeneous composition and inhibit clumping within the fluid. Further, the magnetic component may be paramagnetic, diamagnetic, ferromagnetic, or any combination thereof.

In various embodiments, the heat transfer fluid 115 may be a colloidal liquid comprising magnetic particles that are suspended in a carrier fluid. For example, the heat transfer fluid 115 may further comprise an aqueous component. The aqueous component may be water or a mixture of water and another substance. In other embodiments, the carrier fluid may be ethylene glycol or another type of liquid that possesses thermal transfer properties and doesn't interfere with the functioning properties of the magnetic component.

The concentration of the magnetic component in the heat transfer fluid 115 may vary according to the design needs of the heat transfer circuit 100. For example, a system that requires more heat transfer capability may require a higher concentration of magnetic component in the heat transfer fluid 115. In accordance with one embodiment, the flow rate of the heat transfer fluid 115 through the fluid flow passageway 110 may be proportional to the concentration of the magnetic component in the heat transfer fluid 115. For example, increasing the concentration of magnetic component in the heat transfer fluid may increase the flow rate of the heat transfer fluid 115.

According to one or more embodiments, the heat transfer circuit 100 may further include a heat reservoir 120. The heat reservoir may be in thermal communication with at least a portion of the fluid flow passageway 110. For example, as illustrated in FIG. 1 by the dashed line, the fluid flow passageway 110 may be disposed within the heat reservoir 120. As used herein, the term “heat reservoir” refers to any device or material that radiates a heat load. For example, in certain instances the heat reservoir 120 may be a power resistor.

In some embodiments, the heat transfer circuit 100 further includes a cooling reservoir 125. The cooling reservoir may be in thermal communication with at least a portion of the fluid flow passageway. For example, as illustrated in FIG. 1 by the dashed line, the fluid flow passageway may be positioned or otherwise disposed within the cooling reservoir 125. As used herein, the term “cooling reservoir” refers to any device or material that is capable of producing a cooling effect. For example, the cooling reservoir 125 may be a chiller or other device that radiates a cooling load. In at least one embodiment, the cooling reservoir 125 may be a container filled with ice or ice and cooled water. In another embodiment, the cooling reservoir 125 may be a cooling jacket that surrounds at least a portion of the fluid flow passageway.

In various embodiments, the heat reservoir 120 may be in thermal communication with a first portion of the fluid flow passageway 110 and the cooling reservoir 125 may be in thermal communication with a second portion of the fluid flow passageway 110. In other embodiments, the heat reservoir 120 and/or the cooling reservoir 125 may be positioned or otherwise in thermal communication with multiple portions of the fluid flow passageway 110.

According to a further aspect, the heat transfer circuit 100 further includes a control module 130. The control module 130 may be in communication with the electromagnetic field coils 105 using communication means 135. The communication means 135 may be attached to the electromagnetic field coil 105 at one or both ends of the coil. For example, one end of the coil 105 may be controlled by the control module 130 to turn the coil 105 on or off. The other end of the coil 105 may have a current applied to it, as controlled by the control module 130. In certain instances, the communication means 135 may include or be constructed from a conductive material, thereby allowing electric current to be transferred to the electromagnetic field coil 105. One or more portions of the communication means may further be at least partially covered by an insulating material, to protect external objects from the electric current.

In one embodiment, the control module 130 is configured to control the operation of the electromagnetic field coils 105 to apply an electric current to the electromagnetic field coils 105 through a communication means 135. For example, the control module 130 may further comprise a computer or other device that is configured to control the operation of the electromagnetic field coils 105 to control the flow of electric current. In some embodiments, the control module 130 may include one or more drive circuits and each drive circuit may be attached to a single electromagnetic field coil 105. In at least one example, a relay coil may be connected to a transistor that is in turn connected to and controlled by software on a computer. The control module 130 may further include a timer or other device that is configured to turn one or more driver circuits on and off.

The electric current applied to the electromagnetic field coils may be AC or DC and may be applied to produce a constant magnetic field or may be applied in pulses. The source of the current may be from any number of power sources, including one or more components associated with the control module 130.

The control module 130 may be configured to manipulate the electromagnetic field coils 105 to apply current sequentially, which may provide the primary driving force for moving the heat transfer fluid 115 through the fluid flow pathway 110. For example, if three electromagnetic field coils 105 are placed sequentially, current may be applied to the first coil, then the second coil, and finally to the third coil. This generates a magnetic field that moves the heat transfer fluid 115 in a first direction. The control module 130 may also be configured to manipulate the electromagnetic field coils 105 to apply current in a second, opposite direction. Referring to the previous example, current may be applied first to the third coil, then the second coil, and finally the first coil, which generates a magnetic field that moves the heat transfer fluid 115 in the second or opposite direction from the first direction. Although in this example three electromagnetic field coils were used, it is within the scope of this disclosure to include any number of electromagnetic field coils to meet the design and heat transfer needs of the circuit.

In certain embodiments, the fluid flow passageway 110 may be constructed from separate pieces or segments and the separate pieces or segments may be joined together sequentially. The adjacent segments may be joined together using a connector. In a further embodiment, the connector may be a heat transfer element 150. For example, at least one heat transfer element 150 may be positioned in a pair of adjacent fluid flow passageway segments. The heat transfer element 150 may be in thermal communication with the heat transfer fluid 115. For example, the heat transfer element 150 may be constructed in the shape of a cylinder or any other shape that allows the fluid to transfer through at least a portion of its interior. Further, the heat transfer element 150 may be made from a thermally conducting material, such as one or more types of metal material. For example, the heat transfer element 150 may be made from brass, and the heat transfer element 150 may be a brass barb. In some embodiments, the heat transfer element 150 may be positioned within at least one of the heat reservoir 120 and the cooling reservoir 125, and thus may aid in transferring thermal energy to and from the heat transfer fluid 115 and/or the flow passageway 110.

In some embodiments, the heat transfer element 150 may be constructed from one or more pieces or sections. For example, each of two sections of the heat transfer element 150 may be positioned in each of the respective adjacent sections of the fluid flow passageway and further joined together by a third section. The heat transfer element 150 may be positioned in the fluid flow passageway 110 to form a liquid-tight seal, which may be accomplished through a threaded joint or compression-type fitting. In some embodiments, the heat transfer element 150 may be a single piece positioned and clamped in between the two adjacent sections of fluid flow passageway 110. In some embodiments, the entirety of the heat transfer element 150 may be positioned within the fluid flow passageway 110, whereas in other embodiments, a portion or portions of the heat transfer element 150 may be exposed or external to the fluid flow passageway 110.

In one or more embodiments, gravity may be used in addition to the magnetic field produced by the electromagnetic field coils 105 to move the heat transfer fluid 115 through the fluid flow passageway 110. For example, one or more portions of the fluid flow passageway 110 may be positioned lower or higher than other portions, thereby creating a downhill gradient to promote the flow of the heat transfer fluid 115 through the fluid flow passageway 110.

In accordance with one or more embodiments, the fluid flow passageway 110 may form a closed loop or circuit. The closed circuit may be formed from the heat reservoir 120 through the cooling reservoir 125 to the electromagnetic field coil(s) 105 and back again to the heat reservoir 120. As will be appreciated by one of skill in the art, the heat transfer circuit may include one or more of each of the components included in the circuit. For example, multiple heat reservoirs 120 and cooling reservoirs 125 may be included in the circuit. These may be positioned in series, for example, a series of heat reservoirs 120 followed by a series of cooling reservoirs 125, or an alternate arrangement may be created by placing a cooling reservoir 125 adjacent a heating reservoir 120. In a further example, one or more heat reservoirs 120 and cooling reservoirs 125 may be configured to form a parallel arrangement.

In some embodiments, one or more components may be omitted. For example, the cooling reservoir 125 may be omitted in instances where the combination of the heat transfer fluid 115 and the fluid flow passageway 110 are sufficient to absorb or transfer the desired amount of heat out of the heat reservoir 120. In such an example, air or gas surrounding the fluid flow passageway 110 may function as a cooling reservoir, since thermal energy may be transferred through the walls of the fluid flow passageway 110 into the surrounding air or gas. Using similar logic, some embodiments may exclude the heat reservoir 120. This situation may arise in instances where the electromagnetic field coil(s) 105 are constructed from a conducting material that generates heat when the current is applied. In some embodiments, both the electromagnetic field coil(s) 105 and the heat reservoir 120 may generate heat.

According to a further embodiment, multiple fluid flow passageways 110 may be used to form a configuration that functions in a similar way as a heat exchanger. For example, a first heat transfer circuit may be in thermal contact with a heat reservoir 120 and a second heat transfer circuit may be in thermal contact with a cooling reservoir 125. The fluid flow passageways 110 of each respective heat transfer circuit may be arranged parallel to each other with heat transfer fluid 105 flowing in opposite directions, so as to exchange heat.

In various embodiments, one or more alternatives to the electromagnetic field coil 105 may be used for creating the magnetic field. For example, in certain instances, a magnetic assembly comprising permanent magnets, electromagnets, superconducting magnets, or any other type of magnet may be used to create the magnetic field.

According to at least one embodiment, one or more sensors may be included in the heat transfer circuit. For example, sensors may be positioned to be in communication with one or more components of the heat transfer circuit, such as the heat transfer fluid. The sensors may be configured to detect or otherwise determine one or more properties of the heat transfer fluid, such as temperature and/or flow rate. The sensors may further be in communication with the control module 130. In one example, a sensor may be used to determine the temperature of the heat reservoir 120. When the temperature reaches a predetermined value, then the control module 130 may be programmed to initiate the movement of heat transfer fluid 115 through the circuit.

At least one embodiment may include one or more fans or other blower-type of device that is configured for moving air. The fan(s) may be positioned in multiple positions in the system to aid in the heat transfer process, or to provide a source of heated or cooled air to an external area, such as a room.

Having thus described several aspects of at least one example, it is to be appreciated that various alterations, modifications, and improvements will readily occur to those skilled in the art. For instance, examples disclosed herein may also be used in other contexts. Such alterations, modifications, and improvements are intended to be part of this disclosure, and are intended to be within the scope of the examples discussed herein. Accordingly, the foregoing description and drawings are by way of example only.

What is claimed is:

1. A heat transfer circuit, comprising:
a fluid flow passageway;
a heat transfer fluid disposed within the fluid flow passageway, the heat transfer fluid comprising at least one magnetic component;
at least one reservoir in thermal communication with the fluid flow passageway;
at least one electromagnetic field coil arranged along at least a portion of the fluid flow passageway, the electromagnetic field coil being configured to generate a magnetic field; and
a control module in communication with the at least one electromagnetic field coil to control the operation of the at least one electromagnetic field coil.

2. The heat transfer circuit of claim 1, wherein the at least one electromagnetic field coil is a plurality of electromagnetic field coils arranged sequentially.

3. The heat transfer circuit of claim 2, wherein each electromagnetic field coil of the plurality of electromagnetic field coils has a positive pole and a negative pole, and the positive pole of each electromagnetic field coil is positioned adjacent to the negative pole of an adjacent electromagnetic field coil of the sequential arrangement.

4. The heat transfer circuit of claim 2, wherein the control module is configured to activate each electromagnetic field coil sequentially in a first direction and a second direction.

5. The heat transfer circuit of claim 2, wherein each electromagnetic field coil of the plurality of electromagnetic field coils is spaced substantially equidistant from each other.

6. The heat transfer circuit of claim 1, wherein the at least one reservoir includes a heat reservoir in thermal communication with a first portion of the fluid flow passageway.

7. The heat transfer circuit of claim 6, wherein the at least one reservoir further includes a cooling reservoir in thermal communication with a second portion of the fluid flow passageway.

8. The heat transfer circuit of claim 7, wherein the fluid flow passageway forms a closed circuit.

9. The heat transfer circuit of claim 7, wherein the fluid flow passageway is constructed from a plurality of fluid flow passageway segments arranged sequentially, the heat transfer circuit further comprising at least one heat transfer element positioned in a pair of adjacent fluid flow passageway segments, the at least one heat transfer element in thermal communication with the heat transfer fluid.

10. The heat transfer circuit of claim 9, wherein a first heat transfer element is in thermal communication with the heat reservoir and a second heat transfer element is in thermal communication with the cooling reservoir.

11. The heat transfer circuit of claim 1, wherein the heat transfer fluid further comprises an aqueous component.

12. The heat transfer circuit of claim 1, wherein the at least one magnetic component comprises nanoparticles of iron.

13. The heat transfer circuit of claim 1, wherein the at least one fluid flow passageway is a tubular structure with an annular fluid chamber.

14. A method of transferring thermal energy in a heat transfer circuit, the heat transfer circuit comprising a fluid flow passageway, a heat transfer fluid disposed within the fluid flow passageway, a reservoir, at least one electromagnetic field coil, and a control module, the method comprising:
positioning the at least one electromagnetic field coil along at least a portion of the fluid flow passageway;
using the control module to apply power to the at least one electromagnetic field coil to generate a magnetic field that moves the heat transfer fluid through the fluid flow passageway; and
passing the heat transfer fluid through the reservoir.

15. The method of claim 14, wherein the at least one electromagnetic field coil is a plurality of electromagnetic field coils and the method further comprises:
positioning each electromagnetic field coil of the plurality of electromagnetic field coils sequentially along at least a portion of the fluid flow passageway; and
using the control module to sequentially apply power to each electromagnetic field coil of the plurality of electromagnetic field coils in a first direction to move the heat transfer fluid through the fluid flow passageway in the first direction.

16. The method of claim 15, further comprising using the control module to apply power to each electromagnetic field coil in a second direction, wherein the second direction is opposite the first direction.

17. The method of claim 15 wherein each electromagnetic field coil is controlled by a separate drive circuit.

18. The method of claim 14, wherein the heat transfer fluid comprises at least one magnetic component, and a flow rate of the heat transfer fluid through the fluid flow passageway is proportional to the concentration of the at least one magnetic component in the heat transfer fluid.

19. The method of claim 14, wherein the reservoir includes a heat reservoir and a cooling reservoir, and wherein passing the heat transfer fluid through the heat reservoir and the cooling reservoir is performed in a continuous circuit.

20. The method of claim 19, wherein thermal energy is transferred from the heat reservoir to the cooling reservoir through the heat transfer fluid.
